(19) United States
(12) Patent Application Publication
(10) Pub. No.: US 2023/0350022 A1
(43) Pub. Date: Nov. 2, 2023

(54) OPTOELECTRONIC SEMICONDUCTOR DEVICE, OPTOELECTRONIC SEMICONDUCTOR APPARATUS, METHOD OF OPERATING THE OPTOELECTRONIC SEMICONDUCTOR DEVICE, AND BIOSENSOR

(71) Applicant: OSRAM OPTO SEMICONDUCTORS GMBH, Regensburg (DE)

(72) Inventor: Hubert HALBRITTER, Dietfurt-Toeging (DE)

(21) Appl. No.: 18/044,391

(22) PCT Filed: Aug. 23, 2021
(86) PCT No.: PCT/EP2021/073226

§ 371 Date: Mar. 8, 2023

(30) Foreign Application Priority Data
Sep. 9, 2020 (DE) 10 2020 123 559.3

(51) Int. Cl. G01S 7/481; H01L 25/16; H01S 5/026; H01S 5/062; H01S 5/183; H01S 5/02255; G01S 17/58; G01S 17/34

(52) U.S. Cl. CPC G01S 7/4811; H01L 25/167; H01S 5/0264; H01S 5/0622; H01S 5/18302; H01S 5/18397; H01S 5/02255; G01S 17/58; G01S 17/34; G01S 7/4818; G01S 7/4815; H01S 5/3095

(57) ABSTRACT

An optoelectronic semiconductor component (10) includes a semiconductor stack (109) in which a surface-emitting laser diode (103) and a photodetector (105) are placed vertically on top of one another. The optoelectronic semiconductor component (10) additionally includes an electric power source (149) that is adapted to modify a current intensity applied to the surface-emitting laser diode (103), thus allowing an emission wavelength to be modified.

### CROSS-REFERENCE TO RELATED APPLICATIONS

The present application is a national stage entry according to 35 U.S.C. § 371 of PCT application No.: PCT/EP2021/073226 filed on Aug. 23, 2021; which claims priority to German patent application DE 10 2020 123 559.3, filed on Sep. 9, 2020; all of which are incorporated herein by reference in their entirety and for all purposes.

### TECHNICAL FIELD

An optoelectronic semiconductor device and apparatus are specified, in particular an optoelectronic semiconductor device having a semiconductor layer stack, a current source adapted to vary a current in a laser diode of the semiconductor layer stack, and an evaluation device adapted to determine information about a change in distance between the optoelectronic semiconductor device and an object which has reflected the electromagnetic radiation emitted by the laser diode.

### BACKGROUND

LIDAR (“Light Detection and Ranging”) systems, in particular FMCW LIDAR systems (“Frequency Modulated Continuous Wave” LIDAR systems) are increasingly being used in vehicles, for example for autonomous driving. For example, they are used for measuring distances or for recognizing objects. In order to be able to reliably detect objects at greater distances, laser light sources of appropriately high power are required.

In general, attempts are being made to improve existing LIDAR systems.

Moreover, efforts are being made to develop novel optical sensors.

It is an objective to provide an improved optoelectronic semiconductor device and an improved optoelectronic semiconductor apparatus for use in a LIDAR system. Furthermore, it is an objective to provide an improved biosensor.

### SUMMARY

According to embodiments, the object is achieved by the subject matter of the independent claims. Further developments are defined in the dependent claims.

An optoelectronic semiconductor device comprises a semiconductor layer stack in which a surface-emitting laser diode and a photodetector are arranged vertically one above the other.

For example, at least one semiconductor layer of an active zone of the surface-emitting laser diode and at least one semiconductor layer of the photodetector may originate from the same material system. For example, the active zone and at least one semiconductor layer of the photodetector may comprise a compound semiconductor layer comprising the same elements. For example, both the active zone and at least one semiconductor layer of the photodetector may comprise GaAs or a compound semiconductor layer containing GaAs. According to further embodiments, both the active zone and at least one semiconductor layer of the photodetector may comprise InP, GaN or a compound semiconductor layer containing InP or GaN.

The optoelectronic semiconductor device may further comprise a waveguide which is adapted to supply electromagnetic radiation reflected by an object to the photodetector. For example, the waveguide may be a single-mode waveguide. In this manner, the wavefronts of the electromagnetic radiation emitted by the surface-emitting laser diode and of the radiation reflected by the object may be aligned particularly well. When the respective wavefronts are aligned, superimposition of the electromagnetic radiation and thereby mixing are promoted.

The optoelectronic semiconductor device may also comprise an encapsulation, wherein the surface-emitting laser diode is adapted to emit electromagnetic radiation via the encapsulation and the photodetector is adapted to detect the reflected electromagnetic radiation.

According to embodiments, the surface-emitting laser diode comprises a plurality of laser elements stacked vertically one above the other.

According to embodiments, the optoelectronic semiconductor device further comprises a current source which is adapted to vary a current intensity impressed in the surface-emitting laser diode, thus allowing an emission wavelength to be varied.

The optoelectronic semiconductor device may additionally include an evaluation device which is adapted to determine, from a detection signal of the photodetector, information about a change in distance between the optoelectronic semiconductor device and an object which has reflected the electromagnetic radiation emitted by the vertically emitting laser diode.

For example, the detection signal is a periodic signal from which a difference between a frequency of electromagnetic radiation emitted by the surface-emitting laser diode and the frequency of the electromagnetic radiation reflected by the object may be determined.

According to embodiments, an optoelectronic semiconductor apparatus comprises a substrate and a plurality of pixels arranged over the substrate, each comprising a semiconductor layer stack. The semiconductor layer stack each comprises a surface-emitting laser diode and a photodetector, which are arranged vertically one above the other.

The optoelectronic semiconductor apparatus also comprises an array of waveguides which are adapted to supply electromagnetic radiation reflected by an object to a respective one of the photodetectors. For example, the waveguides may be single-mode waveguides.

For example, the surface-emitting laser diodes each comprise a plurality of laser elements which are stacked vertically one above the other.

The optoelectronic semiconductor apparatus further comprises a current source which is adapted to vary a current intensity impressed into at least one of the surface-emitting laser diodes, thus allowing an emission wavelength to be varied. For example, the current source may be adapted to impress different current intensities into two different surface-emitting laser diodes, respectively. According to embodiments, the current source may be adapted to simultaneously drive the surface-emitting laser diodes of the plurality of pixels.

According to embodiments, the optoelectronic semiconductor apparatus further comprises an evaluation device which is adapted to determine, from a detection signal of the photodetector, information about a distance or a relative speed between the optoelectronic semiconductor device and an object which has reflected the electromagnetic radiation emitted by the vertically emitting laser diode.

According to embodiments, the detection signal is a periodic signal from which a difference between a frequency of electromagnetic radiation emitted by the surface-emitting laser diode and the frequency of the electromagnetic radiation reflected by the object may be determined.

According to embodiments, the optoelectronic semiconductor apparatus further comprises an optical element adapted to deflect the direction of electromagnetic radiation emitted by some of the pixels.

A method for operating an optoelectronic semiconductor device comprises impressing a current which varies over time into the surface-emitting laser diode, thereby emitting electromagnetic radiation of a frequency which varies over time. The method also includes detecting a photocurrent through the photodetector and determining a change in a distance between an object reflecting the electromagnetic radiation and the optoelectronic semiconductor device, thereby determining a detection signal.

A method for operating an optoelectronic semiconductor apparatus comprises simultaneously impressing a current which varies over time into a plurality of surface-emitting laser diodes of the pixels, thereby causing electromagnetic radiation of a frequency which varies over time to be emitted by each of the pixels. The method further comprises detecting a photocurrent through the photodetectors of the pixels and determining a positional relationship or a change in the positional relationship between an object reflecting the electromagnetic radiation and the optoelectronic semiconductor device, thereby determining a detection signal.

For example, the detection signal is a periodic signal from which a difference between a frequency of electromagnetic radiation which has been emitted by the surface-emitting laser diode and the frequency of the electromagnetic radiation which has been reflected by the object may be determined.

For example, a different current may respectively be impressed into at least two of the surface-emitting laser diodes.

Further embodiments relate to a biosensor comprising the optoelectronic semiconductor device described above.

Further embodiments relate to a LIDAR system comprising the optoelectronic semiconductor device described above.

### BRIEF DESCRIPTION OF THE DRAWINGS

The accompanying drawings serve to provide an understanding of exemplary embodiments. The drawings illustrate exemplary embodiments and, together with the description, serve for explanation thereof. Further exemplary embodiments and many of the intended advantages will become apparent directly from the following detailed description. The elements and structures shown in the drawings are not necessarily shown to scale relative to each other. Like reference numerals refer to like or corresponding elements and structures.

FIG. 1A shows a schematic cross-sectional view of an optoelectronic semiconductor device according to embodiments.

FIG. 1B shows a cross-sectional view of an optoelectronic semiconductor component according to further embodiments.

FIG. 2A illustrates a configuration of the optoelectronic semiconductor device in operation according to embodiments.

FIG. 2B illustrates a measuring configuration using the optoelectronic semiconductor device according to embodiments.

FIGS. 3A and 3B illustrate further modifications of the optoelectronic semiconductor device.

FIGS. 4A and 4B show further embodiments of the optoelectronic semiconductor device.

FIG. 5A illustrates the operation of an optoelectronic semiconductor apparatus according to embodiments.

FIG. 5B illustrates further elements of the optoelectronic semiconductor apparatus according to embodiments.

FIG. 5C illustrates further elements of the optoelectronic semiconductor apparatus according to embodiments.

FIGS. 6A and 6B illustrate the course of wavefronts during operation of the optoelectronic semiconductor apparatus.

FIG. 7A shows a schematic cross-sectional view of an optoelectronic semiconductor apparatus according to embodiments.

FIG. 7B shows a schematic cross-sectional view of the optoelectronic semiconductor apparatus according to further embodiments.

FIG. 7C shows a schematic cross-sectional view of the optoelectronic semiconductor apparatus according to further embodiments.

FIG. 8 shows an optoelectronic semiconductor apparatus according to further embodiments.

FIG. 9A outlines a method for operating an optoelectronic semiconductor device according to embodiments.

FIG. 9B outlines a method for operating an optoelectronic semiconductor apparatus according to embodiments.

### DETAILED DESCRIPTION

In the following detailed description, reference is made to the accompanying drawings, which form a part of the disclosure and in which specific embodiments are shown for purposes of illustration. In this context, directional terminology such as “top”, “bottom”, “front”, “back”, “over”, “on”, “in front”, “behind”, “leading”, “trailing”, etc. refers to the orientation of the figures just described. As the components of the embodiments may be positioned in different orientations, the directional terminology is used by way of explanation only and is in no way intended to be limiting.

The description of the embodiments is not limiting, since other embodiments may also exist and structural or logical changes may be made without departing from the scope as defined by the claims. In particular, elements of the embodiments described below may be combined with elements from others of the embodiments described, unless the context indicates otherwise.

The terms “wafer” or “semiconductor substrate” used in the following description may include any semiconductor-based structure that has a semiconductor surface. Wafer and structure are to be understood to include doped and undoped semiconductors, epitaxial semiconductor layers, supported by a base, if applicable, and further semiconductor structures. For example, a layer of a first semiconductor material may be grown on a growth substrate made of a second semiconductor material, for example a GaAs substrate, a GaN substrate, or an Si substrate, or of an insulating material, for example sapphire.

Depending on the intended use, the semiconductor may be based on a direct or an indirect semiconductor material. Examples of semiconductor materials particularly suitable for generating electromagnetic radiation include, without limitation, nitride semiconductor compounds by means of which, for example, ultraviolet, blue or longer-wave light may be generated, such as GaN, InGaN, AlN, AlGaN, AlGaInN, AlGaInBN; phosphide semiconductor compounds by means of which, for example, green or longer-wave light may be generated, such as GaAsP, AlGaInP, GaP, AlGaP; and other semiconductor materials such as GaAs, AlGaAs, InGaAs, AlInGaAs, SiC, ZnSe, ZnO, Ga₂O₃, diamond, hexagonal BN; and combinations of the materials mentioned. The stoichiometric ratio of the compound semiconductor materials may vary. Other examples of semiconductor materials may include silicon, silicon germanium, and germanium. In the context of the present description, the term “semiconductor” also includes organic semiconductor materials.

The term “substrate” generally includes insulating, conductive or semiconductor substrates.

The term “vertical” as used in this description is intended to describe an orientation which is essentially perpendicular to the first surface of a substrate or semiconductor body. The vertical direction may correspond, for example, to a direction of growth when layers are grown.

The terms “lateral” and “horizontal”, as used in the present description, are intended to describe an orientation or alignment which extends essentially parallel to a first surface of a semiconductor substrate or semiconductor body. This may be the surface of a wafer or a chip (die), for example.

The horizontal direction may, for example, be in a plane perpendicular to a direction of growth when layers are grown.

In the context of this description, the term “electrically connected” means a low-ohmic electrical connection between the connected elements. The electrically connected elements need not necessarily be directly connected to one another. Further elements may be arranged between electrically connected elements.

The term “electrically connected” also encompasses tunnel contacts between the connected elements.

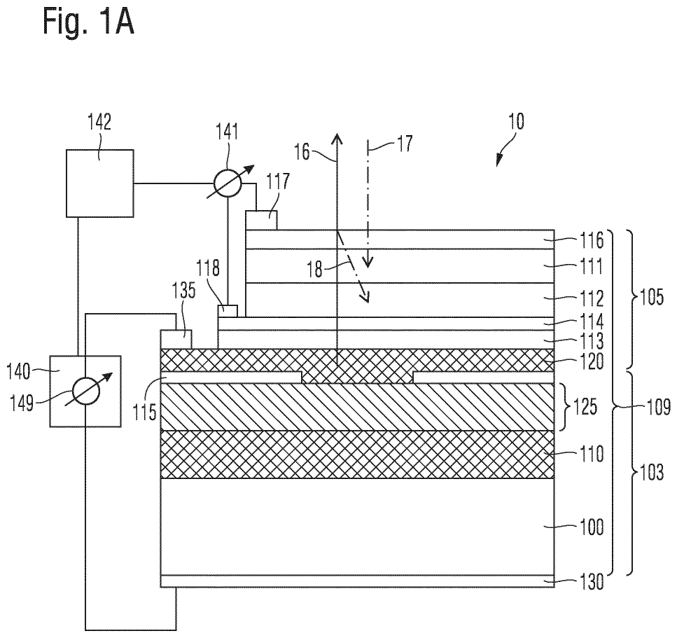

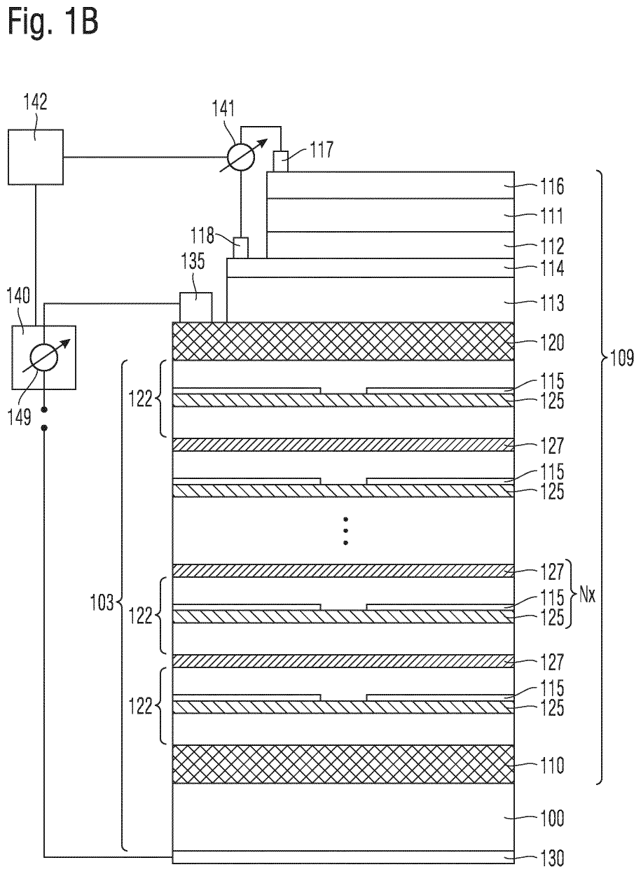

FIG. 1A shows a schematic cross-sectional view of an optoelectronic semiconductor device according to embodiments. The optoelectronic semiconductor device 10 comprises a semiconductor layer stack 109 in which a surface-emitting laser diode 103 and a photodetector 105 are arranged vertically one above the other.

In general, according to all of the embodiments described here, the term “photodetector” refers to a general detection apparatus for electromagnetic radiation. The detection apparatus may include semiconductor materials, for example. According to embodiments, the photodetector may include semiconductor materials. For example, the photodetector may comprise a photodiode having a pn junction, a metal-isolator-metal structure, a metal-semiconductor-metal structure, a tunnel junction, Schottky structures, or photoconductive apparatuses. For example, if a polarity is suitably selected, the photodetector may have a non-linear current-voltage characteristic.

The surface-emitting laser diode represents a VCSEL (“Vertical-Cavity Surface-Emitting Laser”). The latter comprises a first resonator mirror 110, a second resonator mirror 120 and an active zone 125 for beam generation. The surface-emitting laser diode comprises an optical resonator formed between the first and second resonator mirrors 110, 120. The optical resonator extends in a vertical direction.

The first and second resonator mirrors 110, 120 may each be configured as a DBR layer stack (“Distributed Bragg Reflector”) and may comprise a plurality of alternating thin layers with different refractive indices. The thin layers may each be composed of a semiconductor material or of a dielectric material. For example, the layers may alternately have a high refractive index (n>3.1 when using semiconductor materials, n>1.7 when using dielectric materials) and a low refractive index (n<3.1 when using semiconductor materials, n<1.7 when using dielectric materials). For example, the layer thickness may be λ/4 or a multiple of λ/4, where λ indicates the wavelength of the light to be reflected in the respective medium. The first or the second resonator mirror may, for example, comprise 2 to 50 individual layers. A typical layer thickness of the individual layers may be about 30 to 150 nm, for example 50 nm. The layer stack may further include one or two or more layers that are thicker than about 180 nm, for example thicker than 200 nm.

The first resonator mirror 110 may include semiconductor layers of the first conductivity type, for example p-type. The second resonator mirror 120 may include semiconductor layers of the second conductivity type, for example n-type. According to further embodiments, the first and/or the second resonator mirror 110, 120 may be composed of dielectric layers. In this case, semiconductor layers of the first conductivity type may be disposed between the first resonator mirror 110 and the active zone 125. Furthermore, semiconductor layers of the second conductivity type may be disposed between the second resonator mirror 120 and the active zone 125.

The active zone 125 may, for example, comprise a pn junction, a double heterostructure, a single quantum well structure (SQW, single quantum well) or a multiple quantum well structure (MQW, multi quantum well) for generating radiation. The term “quantum well structure” does not imply any particular meaning here with regard to the dimensionality of the quantization. Therefore it includes, among other things, quantum wells, quantum wires and quantum dots as well as any combination of these structures. For example, the materials of the active zone 125 may include GaAs. According to further embodiments, materials of the active zone may include GaN or InP.

The surface emitting laser diode 103 may further comprise an aperture stop 115 arranged in the semiconductor layer stack 109. For example, the aperture stop 115 may be disposed adjacent to the active zone 125. The aperture stop 115 is insulating, for example, and limits the flow of current and thus the injection of charge carriers onto the area between the bordering parts of the aperture stop 115.

The first resonator mirror 110 is formed over a substrate 100, for example. The first resonator mirror 110 may, for example, be contacted via a first contact element 130 and optionally via the substrate 100. For example, the first contact element 130 may be arranged on the side of the substrate 100 facing away from the first resonator mirror 110. Laser emission may be effected by impressing a current via the first contact element 130 and a second contact element 135. The second contact element may be formed in electrical contact with the second resonator mirror 120.

The wavelength of the emitted electromagnetic radiation may be modulated by modulating the impressed current intensity. For example, a modulation device 140 may include a current source 149. The modulation device 140 may be adapted to modulate the impressed current, for example within the range of a few μA. Due to the modulation of the current intensity impressed, a modulation of the charge carrier density occurs, which leads to a modification in the refractive index in the optical resonator. As a result the wavelength is shifted. Furthermore, an increased charge carrier density causes an increase in temperature, which also leads to a modification in the emission wavelength. Accordingly, the emission wavelength may be modulated within the MHz to GHz range.

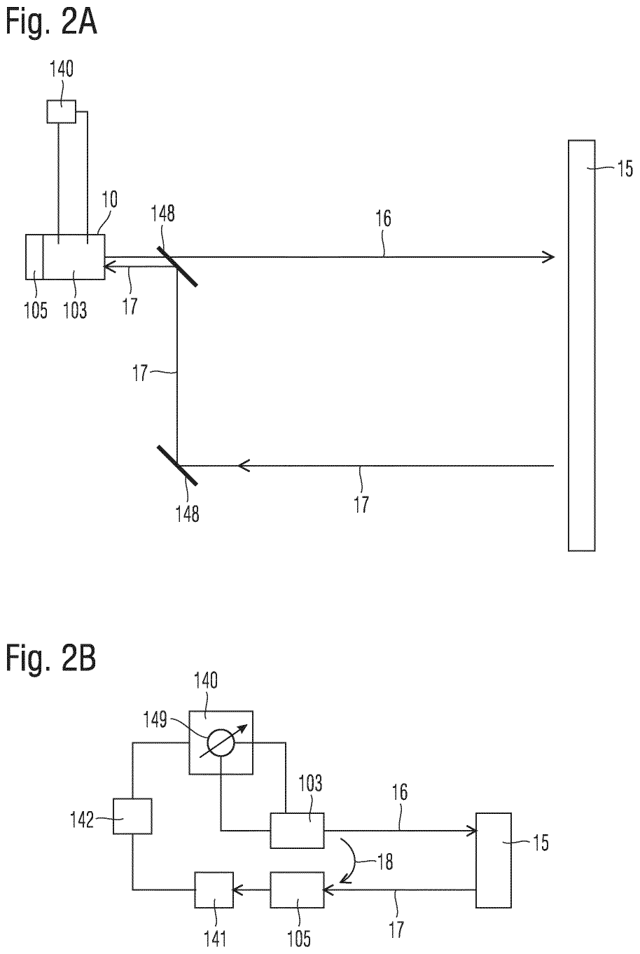

The semiconductor layer stack 109 further comprises layers of a photodetector 105. For example, the photodetector 105 may be implemented as a diode and may comprise a first semiconductor layer 112 of a first conductivity type, for example p-type, and a second semiconductor layer 111 of a second conductivity type, for example n-type. According to further embodiments, the photodetector 105 may be implemented by any other suitable apparatus as discussed above. The first semiconductor layer 112 may be connected to a first contact layer 114. The second semiconductor layer 111 may be connected to a second contact layer 116. A measuring device 141 is adapted to determine a photocurrent via a first detector contact element 118 and a second detector contact element 117. The first detector contact element 118 is connected to the first contact layer 114. The second detector contact element 117 is connected to the second contact layer 116. According to embodiments, a signal from the modulation device 140 and the measuring device 141 is fed to an evaluation device 142. The latter is adapted to derive desired information from a signal. This will be discussed in more detail below with reference to FIGS. 2A and 2B.

The surface-emitting laser diode 103 and the photodetector 105 are stacked vertically one above the other. This means that the laser diode 103 may, for example, be arranged above or below the photodetector 105, the terms “above” and “below” relating to a direction of layer growth.

Due to the relatively thin layer thickness of the first and second semiconductor layers 112, 111 of the photodetector 105, only part of the electromagnetic radiation emitted by the surface-emitting laser diode 103 is absorbed by the photodetector 105. For example, the first and second semiconductor layers may have a total layer thickness of less than 1 μm, for example approximately 200 nm. If the photodetector comprises a tunnel diode or a Schottky contact, this may have a total layer thickness of less than approximately 200 nm, for example 50 to 100 nm.

FIG. 1A shows a beam 16 emitted by the surface laser diode. A portion of the emitted beam 16 is internally reflected and constitutes an internally reflected beam 18. FIG. 1A further illustrates a beam 17 which is reflected by an object (not shown in FIG. 1A). A part of the emitted beam 16 which has been reflected by an object (not shown) returns into the optoelectronic semiconductor device 10 as a reflected beam 17.

FIG. 1B shows a schematic cross-sectional view of an optoelectronic semiconductor device, in which the surface-emitting laser diode 103 comprises a plurality of laser elements 122.

A plurality of individual laser elements 122 is arranged between a first resonator mirror 110 and a second resonator mirror 120. The individual laser elements 122 are connected to one another via tunnel junctions.

The semiconductor layer stack 109 thus comprises a plurality of active zones 125 which are connected to one another, for example via tunnel junctions 127. In this manner, the semiconductor layer stack 109 may comprise more than three, for example about six or more than six, laser elements 122. The laser elements 122 may furthermore comprise suitable semiconductor layers of the first and second conductivity types, each layer being adjacent to the active zone 125 and connected thereto.

The tunnel junctions 127 may each comprise sequences of p⁺⁺ doped layers and n⁺⁺ doped layers, through which the individual laser elements 122 may be connected to one another. The p⁺⁺ and n⁺⁺ doped layers are reverse connected to the associated laser elements 122. According to embodiments, the layer thicknesses of the individual semiconductor layers of the laser elements 122 are dimensioned in such a way that the tunnel junctions 127 are arranged, for example, at nodes of the standing wave that forms. In this manner, the emission wavelength of the surface-emitting laser diode 103 may be stabilized. By stacking multiple laser elements 122 one above the other, higher power densities and furthermore narrower line widths of the emitted laser beam may be achieved. The sequence of very highly doped layers of the first and second conductivity types and optionally intermediate layers constitutes a tunnel diode. By using these tunnel diodes, the respective laser elements 122 may be connected in series.

FIG. 2A shows a schematic measuring configuration using the optoelectronic semiconductor device 10 described. The laser beam 16 emitted by the optoelectronic semiconductor device 10 is radiated onto an object 15. The beam 17 reflected by the object 15 is, for example, fed back to the optoelectronic semiconductor component 10 through a suitable optical element 148. However, depending on the configuration of the optoelectronic semiconductor device, the optical element 148 may also be omitted. If suitable in-coupling into the optoelectronic semiconductor component is provided, the reflected beam 17 is superimposed and thus mixed with internally reflected beams that have been reflected within the optoelectronic semiconductor device 10. The superimposed signal may then be detected by the photodetector 105. From this signal, the difference frequency of the two superimposed signals may be determined, as will be discussed below. As depicted in FIG. 1A, part of the laser beam emitted by the surface-emitting laser 103 may be reflected at layers within the semiconductor layer stack 109 and thereby form the reflected beam 18. Superimposition of the internally reflected beam 18 with a reflected beam 17 may be effected, for example, if the respective wavefronts of the beams are superimposed exactly. Furthermore, the coherence condition may be fulfilled. Due to the fact that the surface-emitting laser diode is a single-mode laser diode and may be operated in a single laser mode, superimposition may also take place without the coherence condition being fulfilled. For example, since the surface-emitting laser diode is a single-mode laser diode, the best possible superimposition of the transmitted and received wavefronts may be achieved. For example, a line width of the surface-emitting laser diode may be in the MHz range. For example, an output power of the surface-emitting laser diode 103 may be less than 10 mW.

If several laser elements 122 are stacked one above the other, the line width may be less than 1 MHz. The power may be in a range between 50 and 100 mW, depending on the number of laser elements 122 stacked one above the other.

The modulation device 140 may include a current source 149. The modulation device is provided in order to modulate the wavelength of the emitted light. For example, a frequency shift may be effected by amplitude modulation, i. e., a modulation of the current intensity.

The object 15 may be a human being or another living being, for example. By using the optoelectronic semiconductor device 10, the pulse of the person, for example, may be determined. According to further embodiments, the flow rate or other flow properties of the blood may also be determined. According to embodiments, the optoelectronic semiconductor device 10 thus constitutes a biosensor. For example, the optoelectronic semiconductor device 10 may be integrated into a wristwatch.

FIG. 2B schematically illustrates the measuring principle underlying embodiments. The measuring principle corresponds to that of an FMCW LIDAR system. As has been described, the laser beam 16 emitted by the surface emitting laser diode 103 is reflected by an object 15 and enters the photodetector 105 as a reflected beam 17. The reflected beam 17 is superimposed with the internally reflected beam 18. The beam 17 is coherent with the beam 18, for example, and may be superimposed with the latter in a phase-accurate manner. The internally reflected beam 18 represents an LO (“Local Oscillator”) frequency f_{LO}. The frequency of the reflected beam 17 is delayed due to the propagation time difference that results from reflection at the object, and corresponds to the frequency fₐ. The difference between fₐ and f_{LO} is a measure of the movement and distance of the object 15. From this difference, a person's heart rate may be determined, for example. This means that the difference between fₐ and f_{Lo} is to be determined using the measurement setup. The reflected beam 17 is coherently superimposed with the internally reflected beam 18. The superimposed beam is detected by photodetector 105. In doing so, the difference frequency of the internally reflected beam 18 and the reflected beam 17 is determined. Photodetector 105 is one possible implementation of a mixer. The mixed signal may be represented as follows:

i_{sig}=iₐ+i_{LO}+2\sqrt{iₐi_{LO}}cos[2π(fₐ−f_{LO})t+(φₐ−φ_{LO})] (1)

The signal detected by the photodetector 105 is therefore a periodic signal the frequency of which corresponds to the difference between fₐ and f_{LO}. The signal detected by the photodetector 105 is captured by a measuring device 141 and then supplied to an evaluation device 142. If needed, a signal from the modulation device 140 may be fed to the evaluation device 142. The signal from the modulation device 140 reflects the time profile of the modulation of the current intensity impressed by the current source 149 and thus the time profile of the modulation of the frequency of the electromagnetic radiation emitted by the surface-emitting laser diode 103.

The frequency of the signal and thus the difference between fₐ and f_{LO} are determined. The difference between fₐ and f_{LO} may be within the MHz range, for example.

Assuming that the reflected beam 17 is to be superimposed with a beam traveling in the same direction, a phase-accurate superimposition may take place, because signal portions of the emitted light are always reflected within the layer stack. Since the measuring method described is very sensitive, measurement may be taken even if only a small portion of the emitted radiation is internally reflected. The optoelectronic semiconductor device illustrated in FIG. 1A is therefore able to detect very small changes in the distance of the object 15. As a result, for example, the pulse of a living being may be measured. At a power of a few mW and a line width within the MHz range, the light signal emitted by the surface-emitting laser diode 103 is able to overcome distances of the order of magnitude of a few 10 m and to achieve a resolution in the μm range. For example, a diameter of the surface-emitting laser diode 103 may be less than 10 μm.

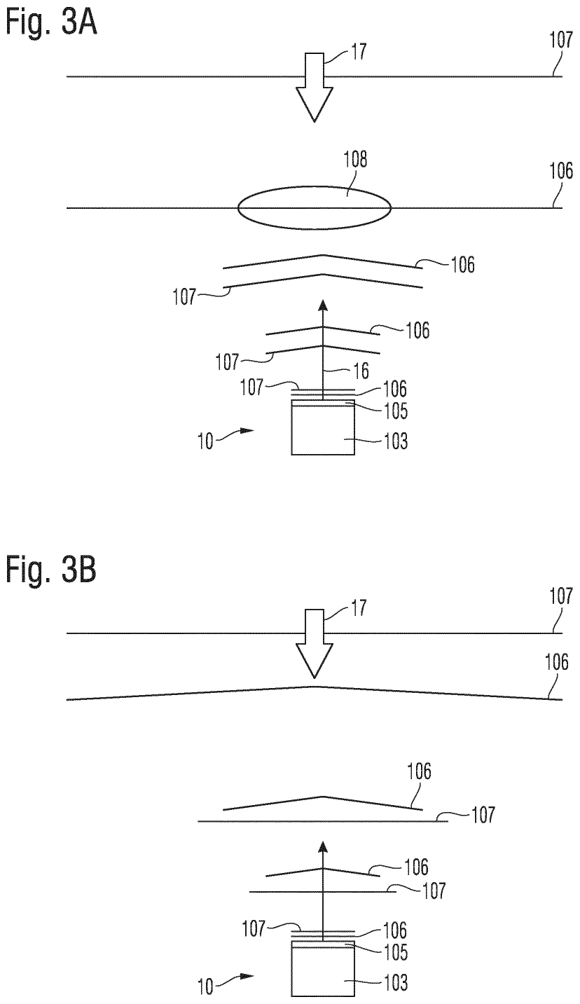

FIG. 3A shows a configuration of the described optoelectronic device 10 using an additional collimator lens 108. FIG. 3A additionally illustrates a representation of the wavefronts, with 106 representing the wavefront of the emitted beam 16 and 107 representing the wavefront of the reflected beam 17. In principle, it may be assumed that the wavefront 106 of the emitted beam is initially planar. Furthermore, it may be assumed that the wavefront of the reflected beam 17 in the photomixer or detector is planar.

FIG. 3B illustrates the configuration of the optoelectronic semiconductor device 10 without using a collimator lens 108. In general, it may be assumed that the collimator lens 108 may be omitted, particularly in the case of short distances (<10 m) from the object 15 to be detected.

According to further embodiments, the optoelectronic semiconductor device 10 may additionally comprise a waveguide 104, for example an optical fiber. The waveguide is arranged between the surface-emitting laser diode 103 and the object 15. The waveguide allows for better incoupling and therefore superimposition of the reflected beam 17 with the internally reflected beam 18 to be ensured.

Incidentally, the photodetector 105 does not necessarily have to be arranged between the surface-emitting laser diode 103 and the object 15. According to further embodiments, the surface-emitting laser diode 103 may also be arranged between the photodetector 105 and the object 15.

The fact that frequency mixing takes place when the reflected beam 17 is superimposed coherently with the internally reflected beam 18, allows or ruling out that signals reflected by other people or from a larger angle are superimposed with the internally reflected signal 18. More specifically, the wavefronts do not match. In this manner, automatic spatial filtering may take place.

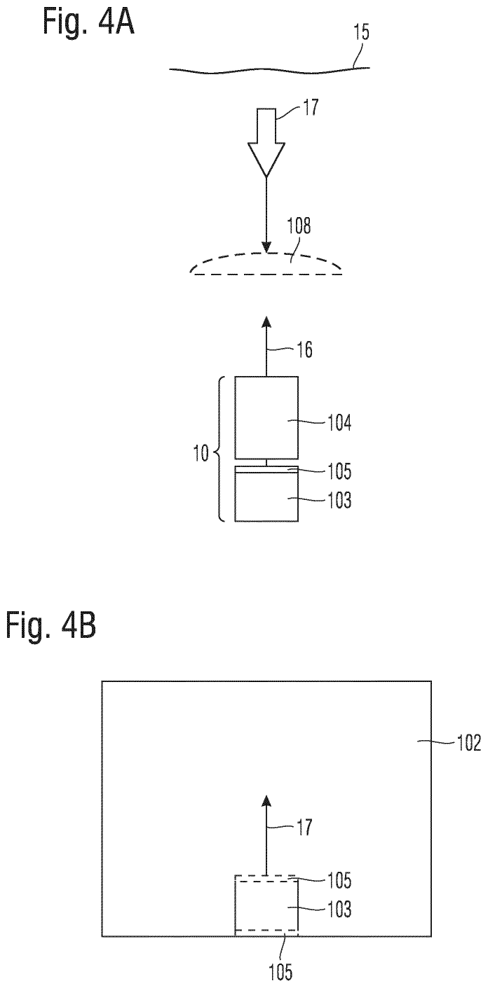

According to further embodiments, the optoelectronic semiconductor device 10 may additionally comprise an encapsulation 102. This is illustrated in FIG. 4B, for example. FIG. 4B shows the surface-emitting laser diode 103 and the photodetector 105 arranged one on top of the other. For example, the photodetector 105 may face away from the emission surface of the surface-emitting laser diode 103 or it be arranged on the emission surface of the surface-emitting laser diode 103. A material of the encapsulation 102 completely surrounds the configuration of the photodetector 105 and the surface-emitting laser diode 103. The material of the encapsulation 102 may comprise the following materials, for example: silicone, epoxy resin or spin-on-glass (SoG). For example, part of the emitted radiation 17 may be reflected at the top of the encapsulation 102 and used for the mixing. According to further embodiments, this signal may also be filtered out or used as an absolute reference.

In general, according to further embodiments, two photodetector structures may also be arranged one on top of the other. For example, as shown in FIG. 4B, the photodetector 105 may be arranged both above and below the surface-emitting laser diode 103. According to further embodiments, the two photodetector structures may also be stacked directly one on top of the other. In this manner, DC components may be eliminated from equation (1). More specifically, the (iₐ+i_{LO}) term may be eliminated from equation (1). This may be done in particular when the phasefronts are shifted by 180° between the photodetectors.

The optoelectronic semiconductor device 10 described thus represents a compact biosensor of simple structure and high sensitivity. The biosensor may be used, for example, to measure the pulse. It is not necessary for the biosensor to contact a person's skin. Rather, the pulse or other vital data of a person may be determined with great accuracy from a distance. In particular, the sensitive detection method using the optoelectronic semiconductor device described, allows for very small (<10 μm) changes in distance to be determined.

In LIDAR applications, in contrast to embodiments described with reference to FIGS. 1 to 4, large-area objects are irradiated with a laser beam. This may be done, for example, by using a scan unit when using a single laser source. According to embodiments described below, this may also be done by using an emitter array, through which the object may be illuminated over a large area.

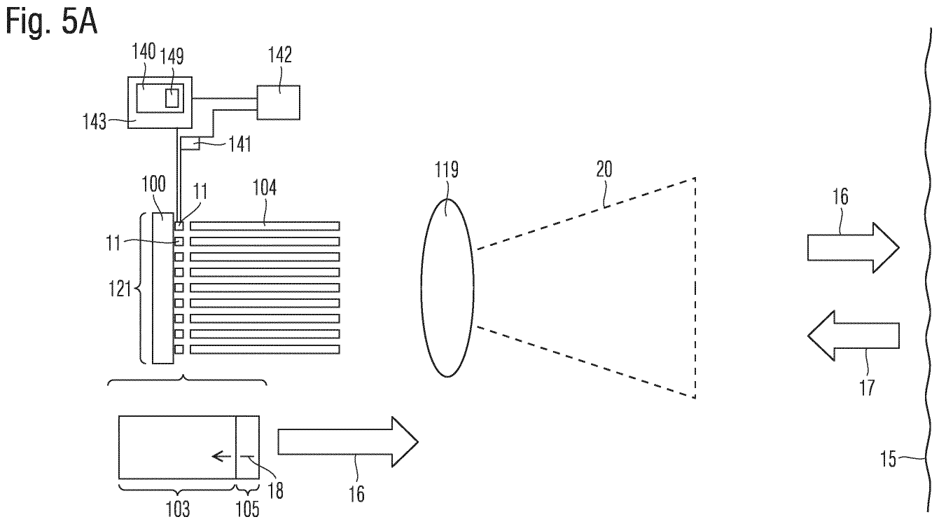

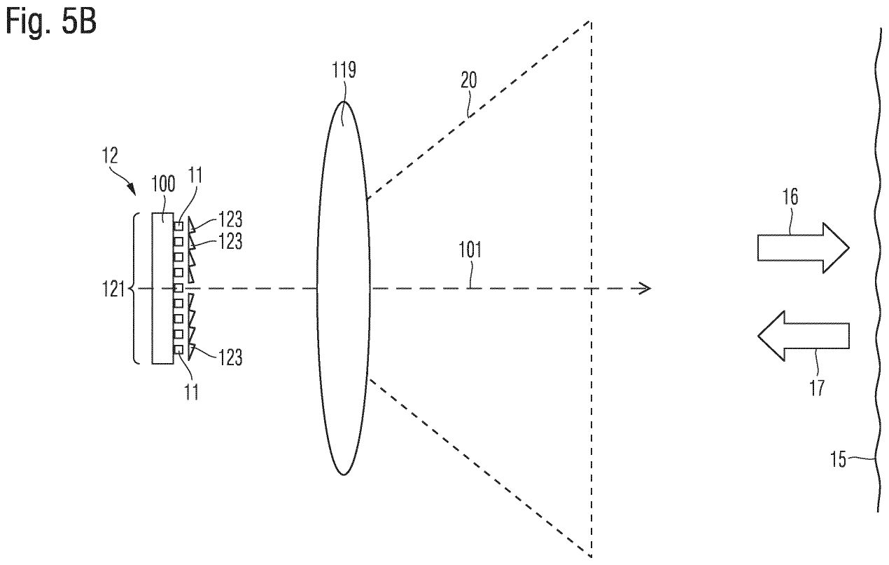

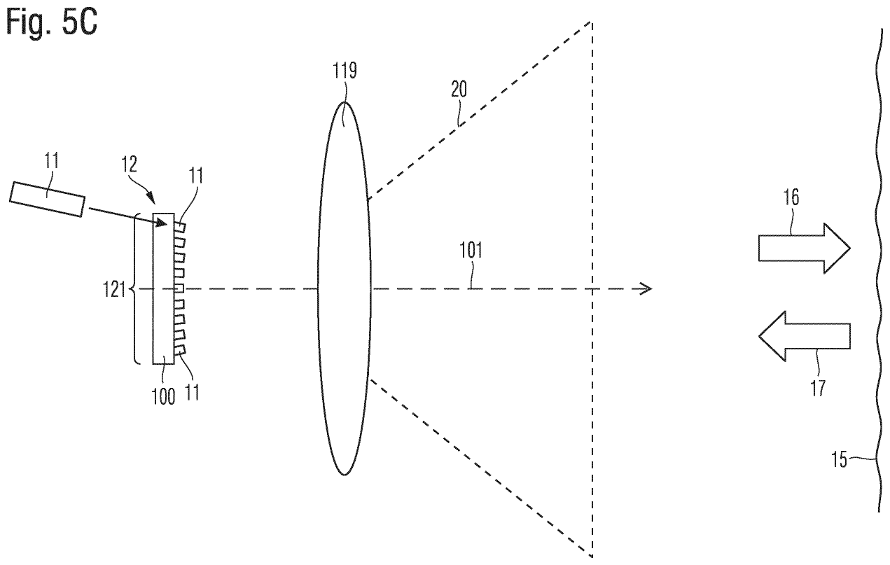

FIG. 5A shows an optoelectronic semiconductor apparatus 12 comprising a substrate 100 and a plurality of pixels 11, each comprising a semiconductor layer stack 109. Each semiconductor layer stack 109 comprises a surface-emitting laser diode 103 and a photodetector 105 which are arranged vertically one on top of the other.

FIG. 5A further illustrates a measuring configuration using the optoelectronic semiconductor apparatus 12. As illustrated in FIG. 5A, a plurality of pixels 11 is arranged over a substrate 100. The substrate 100 may be a GaAs or InP substrate, for example. Each individual pixel 11 may be configured as shown in the lower part of FIG. 5A, for example. More precisely, each of the pixels comprises a semiconductor layer stack 109 in which a surface-emitting laser diode 103 and a photodetector 105 are arranged vertically one on top of the other. Each of the pixels may thus have a configuration as described above with reference to FIGS. 1A and 1B. A waveguide 104 may additionally be associated with each of the individual pixels 11. For example, a pixel 11 may have a diameter of less than 20 μm, for example less than 15 or 11 μm. For example, the distance between adjacent pixels may be smaller than 20 μm, for example less than 10 μm. In general, the number of pixels may be more than 10×10 pixels, for example up to about 1000×1000 pixels. Depending on the desired resolution, however, the number may also be greater. The waveguides 104 may also be omitted.

Each of the pixels 11 emits a single light beam, as discussed, for example, with reference to FIG. 1A or 2A. The plurality of emitted light beams is expanded by an optical element 119 to illuminate a specific field of view 20. The light beams are irradiated onto the object 15 in a manner equivalent to that described with reference to FIG. 2A, and a reflected beam 17 is generated. The reflected beam 17 has a shifted frequency compared to the emitted beam. This beam is projected back onto the array of pixels 11 using optical element 119. Owing to the presence of the plurality of waveguides 104, each of which is associated with the individual pixels 11, each of the light beams 17 emitted by the individual pixels 11 and subsequently reflected is fed back to the associated pixel 11. In this manner, the reflected beam 17 may be superimposed coherently with an internally reflected beam 18.

According to embodiments, the surface-emitting laser diodes 103 may be single-mode lasers. Furthermore, the waveguides 104 may each be single-mode waveguides.

Each pixel 11 thus comprises a surface-emitting laser diode 103 and a photodetector 105. The transmitted wave (local oscillator) mixes with the received signal in the photodetector 105 as discussed with reference to FIG. 2B. For example, the individual pixels 11 may be controlled individually. As a result, each of the individual surface-emitting laser diodes 103, for example, may emit at a slightly different wavelength. Furthermore, the individual surface-emitting laser diodes 103 are not coherent with one another. In this manner and optionally also due to the slightly different emission wavelengths of adjacent laser diodes 103, crosstalk may be avoided. For example, the photodetector 105 of one pixel may be prevented from detecting a mixed signal generated using a laser beam emitted by an adjacent pixel.

In a manner similar to that discussed with reference to FIGS. 1A and 2A, the frequency of each surface-emitting laser diode 103 may be modulated by varying the current intensity.

FIG. 5A further shows a control device 143 adapted to drive each of the surface-emitting laser diodes 103 of the array of pixels 11. The control device 143 may comprise a modulation device 140 which in turn includes a current source 149. For example, the current intensity impressed into each of the surface-emitting laser diodes 103 may be adjusted individually using the control device 143. Furthermore, the control device 143 may be adapted to drive at least two, for example all, of the surface-emitting laser diodes 103 of the array of pixels 11 simultaneously. In this manner, a larger field of view 20 is illuminated at the same time, and the measuring process may be carried out without using a scanning or deflecting unit.

FIG. 5A further shows a measuring device 141 and an evaluation device 142 which have a functionality as described with reference to FIGS. 2A and 2B. The measuring device 141 may detect the mixed signal received from the associated photodetector 105. Furthermore, the evaluation device 142 is adapted to determine the respective difference f_{LO}−fₐ from the received signals and a signal from the modulation device 140, from which, for example, the speed and distance of the object 15 may be determined.

By using the modulation device 140, the measuring device 141, and the evaluation device 142, each individual pixel may be controlled and the signals received from each individual pixel 11 may be evaluated. The modulation device 140 may be configured in such a way that a plurality of pixels 11 are driven simultaneously.

For example, the modulation device 140, the measuring device 141, and the evaluation device 142 or parts thereof may be formed in the substrate 100. Furthermore, the components or parts thereof may be arranged in a separate semiconductor chip which is connected to the substrate 100.

The surface-emitting laser diode 103 may be configured as shown, for example, in FIG. 1A or 1B. If the surface-emitting laser diode 103 comprises a plurality of laser elements stacked vertically one on top of the other, the increased length of the optical resonator allows for narrower line widths and, as a result, better or longer coherence lengths to be achieved. For example, at least 3, for example 5 or more, laser elements 122 may be stacked one on top of the other.

According to further embodiments, additional optical elements, for example microlens arrays or spherical lenses, may be arranged between the array of pixels 11 and the array of waveguides 104. According to further embodiments, an optical system, for example an array of wedge-shaped optical elements or optical micro elements 123, may be connected upstream of the individual pixels 11. For example, the wedge-shaped optical elements or optical micro elements 123 may be provided in order to correct the alignment of the optical wavefronts. In general, optical elements may be provided at the wafer level. The optics may be diffractive, for example. The optical elements may also be configured as so-called array optics, for example an array of microlenses.

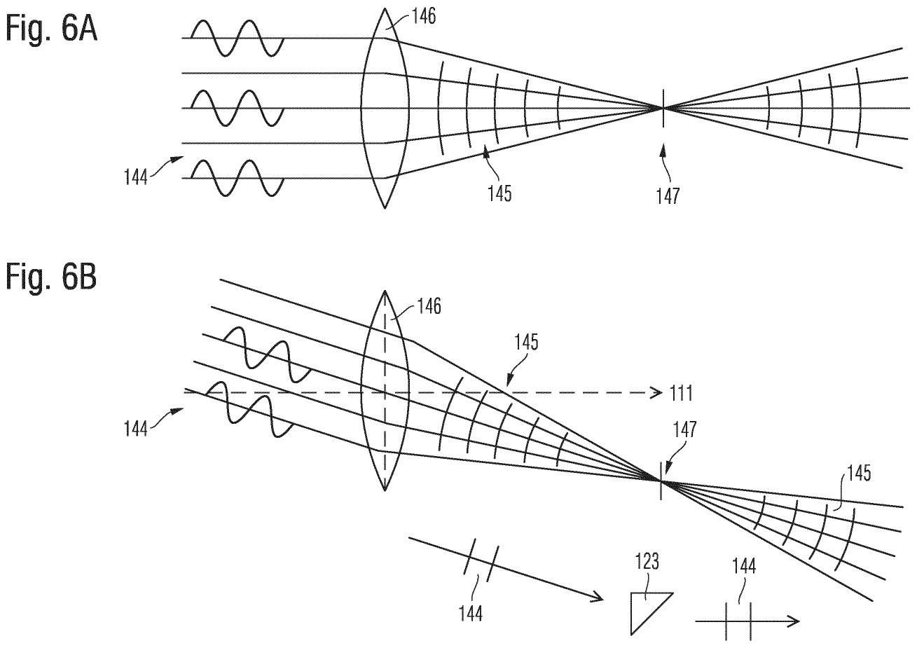

Embodiments comprising wedge-shaped optical elements or optical micro elements 123 are illustrated, for example, in FIG. 5B. As further illustrated in FIG. 5B, the near-axis pixels at the center of the array are not provided with wedge-shaped optical elements 123. This is due to the fact that no additional beam correction by a wedge-shaped optical element or optical micro element 123 is required in the central region of the pixel array 121, as will be discussed below with reference to FIGS. 6A and 6B.

FIG. 5C shows a measuring configuration using an optoelectronic semiconductor apparatus 12 according to further embodiments. As shown in FIG. 5C, the individual pixels are not aligned exactly parallel to an optical axis 101, but are tilted at the edge of the pixel array 121. The term “optical axis” refers to the optical axis 101 defined through the center point of the optical element 122, for example a lens.

The pixels 11 may, for example, be tilted with respect to the optical axis 101 in that the associated semiconductor layer stack 109 is in each case applied in a tilted manner. This may be done, for example, by the growth substrate being bent. According to further embodiments, the individual pixels 11 may also be formed on a curved substrate 100, resulting in a curvature so that, for example, the main surface of the individual layers is not perpendicular to the optical axis 101, particularly in the edge region of the pixel array.

In such a configuration of the individual pixels, optical correction of the wavefronts may be dispensed with. The wavefronts going towards the object are symmetrical to the reflected wavefronts.

FIGS. 6A and 6B illustrate the effect of a wedge-shaped optical element or optical micro element 123 for aligning the wavefronts of off-axis beams. FIG. 6A illustrates the course of wavefronts 144 of a light beam emitted by a near-axis pixel 11. As may be seen, the wavefront 144 of the emitted light beam is planar. Imaging through the lens 146 results in spherical wavefronts 145 in each case. The emitted light beam is focused at focal point 147.

FIG. 6B illustrates the course of wavefronts 144 emitted by off-axis pixels. Unlike in FIG. 6A, these light beams are incident on the lens 146 at an angle. After imaging through the lens 146, spherical wavefronts 145 result. The light beam will likewise be focused at focal point 147. However, the wavefronts impinging on the focal point 147 each run obliquely to the optical axis 111. If a wedge-shaped optical element or optical micro element 123 is introduced upstream of the associated pixel 11, for example, the spherical wavefront 145 is aligned so that it runs parallel to the optical axis 111. The off-axis beams are thus aligned by the wedge-shaped optical element or optical micro element 123.

Therefore optical correction of the wavefronts takes place. The wavefronts 106 moving towards the object 15 run symmetrically to the wavefronts 107 reflected by the object.

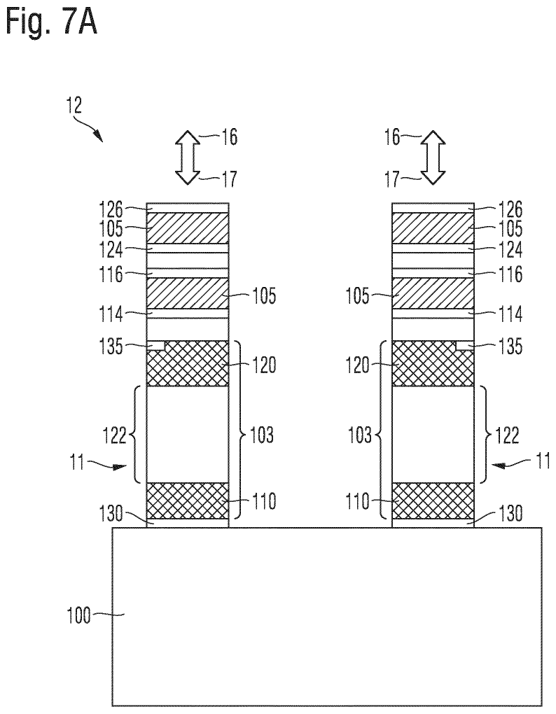

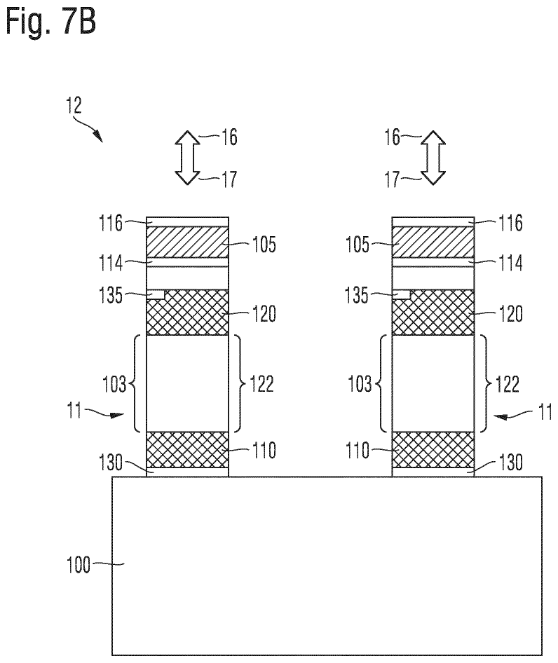

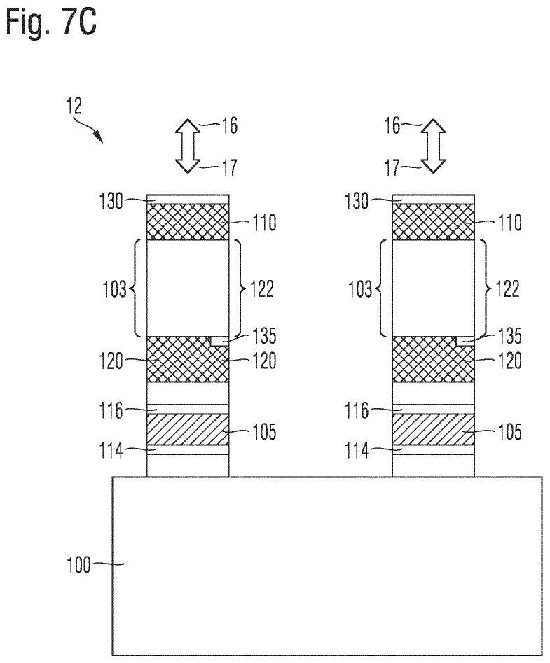

FIG. 7A illustrates the structure of an optoelectronic semiconductor apparatus 12 according to embodiments. A plurality of pixels 11 is arranged over a common substrate 100. For example, the pixels 11 may each be produced by patterning a semiconductor layer stack 109. Each of the pixels comprises a surface-emitting laser diode 103 and a photodetector 105. For example, each of the pixels 11 may comprise a first resonator mirror 110, a second resonator mirror 120, and one or more laser elements 122, each of which comprises an active zone 125. The surface-emitting laser diode 103 may be configured, for example, as shown in FIG. 1A or 1B. The emitting laser diode 103 may be contactable, for example, via a first contact element 130 and a second contact element 135. In addition, two photodetectors 105 may be arranged over a light-emitting surface of the surface-emitting laser diode 103, for example. For example, the first photodetector may comprise a first semiconductor layer of a first conductivity type and a second semiconductor layer of a second conductivity type, as has been described also with reference to FIG. 1A, for example. The first photodetector 105 may be contactable via a first contact layer 114 and a second contact layer 116. In addition, the second photodetector 105 may have the same structure. The second photodetector may be connected via a first contact layer 124 of the second photodetector and a second contact layer 126 of the second photodetector. For example, the first contact layer of the second photodetector 124 may be connected to the second contact layer of the first photodetector. This results in a so-called “Balanced Receiver Structure”. In this case, for example, the phasefronts may be shifted by 180° between the photodetectors. In this manner, for example, DC components may be eliminated from equation (1) described above. More specifically, the (iₐ+i_{LO}) term may be eliminated from equation (1).

FIG. 7B shows a cross-sectional view of an optoelectronic semiconductor apparatus 12 in which only one photodetector 105 is provided in each case.

FIG. 7C shows a further embodiment in which the photodetector 105 is arranged between the substrate 100 and the surface-emitting laser diode 103. In this case, the photodetector 105 is arranged on the side facing away from the emission surface of the surface-emitting laser diode 103.

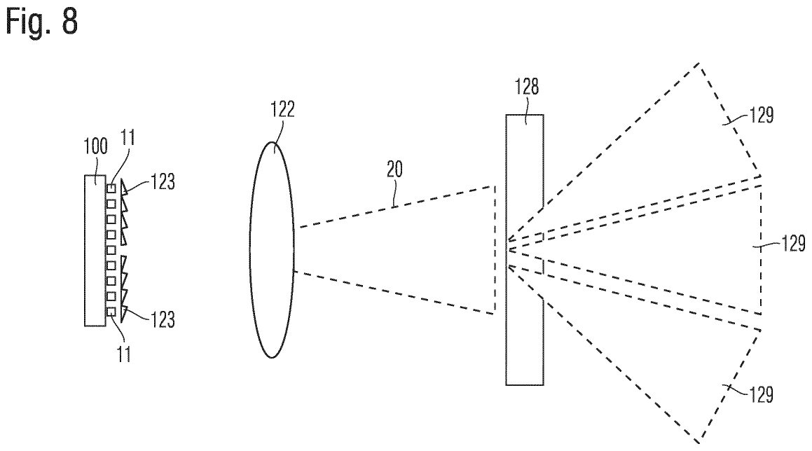

FIG. 8 illustrates a measuring configuration according to further embodiments, in which additional beam expansion may be produced by using a beam deflecting device 128. More specifically, in addition to the components illustrated, for example, in FIG. 5B, a beam deflecting device 128 is introduced into the beam path. The beam deflecting device 128 may be an LCPG (“Liquid Crystal Polarization Grating”), for example. The beam deflecting device 128 may be switchable. Correspondingly, the partial beam may be radiated in a different angular range depending on the switching state. In this manner, the number of pixels 11 is reduced while retaining the resolution and the frame rate. As a result, cost and complexity may be further reduced.

As has been described, the optoelectronic semiconductor apparatus or the optoelectronic semiconductor device may be used to implement an inexpensive, simple system which may be used in a LIDAR system. Since, according to embodiments, the surface-emitting laser diode and the photodetector are arranged in a semiconductor layer stack, the surface-emitting laser diode may be operated within the wavelength range that the photodetector is able to detect. For example, the wavelength may be greater than 1000 nm, so that a risk to the eyes may be reduced, for example.

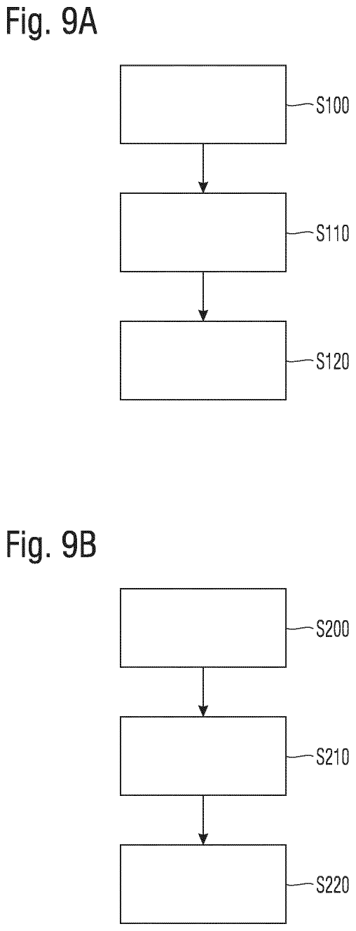

FIG. 9A outlines a method according to embodiments. A method for operating an optoelectronic semiconductor device as described above comprises impressing (S100) a current which varies over time into the surface-emitting laser diode, as a result of which electromagnetic radiation is emitted at a frequency which varies over time. The method further comprises detecting (S110) a photocurrent through the photodetector, thereby obtaining a detection signal, and determining (S120), from the detection signal, a change in a distance between an object which reflects the electromagnetic radiation, and the optoelectronic semiconductor device.

FIG. 9B outlines a method according to further embodiments. A method for operating an optoelectronic semiconductor apparatus as described above comprises simultaneously impressing (S200) a current which varies over time into a plurality of surface-emitting laser diodes of the pixels, as a result of which electromagnetic radiation is emitted by each of the pixels at a frequency which varies over time. The method further includes detecting (S210) a photocurrent through the photodetectors of the pixels, thereby obtaining a detection signal, and determining (S220), from the detection signal, a positional relationship or a change in the positional relationship between an object which reflects the electromagnetic radiation and the optoelectronic semiconductor apparatus.

For example, the current may be impressed simultaneously into the surface-emitting laser diodes of all pixels. In this manner, a large field of view is illuminated at the same time. According to further embodiments, the current may also be impressed simultaneously into only part of the surface-emitting laser diodes. In this manner, groups of pixels 11 may be operated in each case. For example, the current may be impressed only into every second, third, fourth or fifth pixel 11. In this manner, crosstalk may be further suppressed.

According to embodiments, a different current may be respectively impressed into at least two of the surface-emitting laser diodes. In this manner, crosstalk between adjacent pixels may be avoided.

Although specific embodiments have been illustrated and described herein, those skilled in the art will recognize that the specific embodiments shown and described may be replaced by a multiplicity of alternative and/or equivalent configurations without departing from the scope of the invention. The application is intended to cover any adaptations or variations of the specific embodiments discussed herein. Therefore, the invention is to be limited by the claims and their equivalents only.

### LIST OF REFERENCES

10 optoelectronic semiconductor device
11 pixel
12 optoelectronic semiconductor apparatus
15 object
16 emitted beam
17 reflected beam
18 internally reflected beam
19 beam to be detected
20 field of view
100 substrate
101 optical axis
102 encapsulation
103 surface-emitting laser diode
104 waveguide
105 photodetector
106 wavefront (emitted beam)
107 wavefront (reflected beam)
108 collimator lens
109 semiconductor layer stack
110 first resonator mirror
111 second semiconductor layer
112 first semiconductor layer
113 insulating layer
114 first contact layer
115 aperture stop
116 second contact layer
117 second detector contact element
118 first detector contact element
119 optical element
120 second resonator mirror
121 pixel array
122 laser element
123 optical micro element
124 first contact layer of the second photodetector
125 active zone
126 second contact layer of the first photodetector
127 tunnel junction
128 beam deflecting device
129 partial beam
130 first contact element
135 second contact element
140 modulation device
141 measuring device
142 evaluation device
143 control device
144 plane wavefront
145 spherical wavefront
146 lens
147 focal point
148 mirror
149 current source

1. An optoelectronic semiconductor device comprising:
a semiconductor layer stack in which a surface-emitting laser diode and a photodetector are arranged vertically one on top of the other; and
a current source adapted to vary a current impressed in the surface-emitting laser diode, thus allowing an emission wavelength to be varied; and
an evaluation device adapted to determine, from a detection signal of the photodetector, information about a change in distance between the optoelectronic semiconductor device and an object which has reflected the electromagnetic radiation emitted by the surface-emitting laser diode.

2. The optoelectronic semiconductor device according to claim 1, wherein at least one semiconductor layer of an active zone of the surface-emitting laser diode and at least one semiconductor layer of the photodetector originate from the same material system.

3. The optoelectronic semiconductor device according to claim 1, further comprising a waveguide adapted to supply electromagnetic radiation reflected by an object to the photodetector.

4. The optoelectronic semiconductor device according to claim 1, further comprising an encapsulation, wherein the surface-emitting laser diode is adapted to emit electromagnetic radiation via the encapsulation.

5. The optoelectronic semiconductor device according to claim 1, wherein the surface-emitting laser diode comprises a plurality of laser elements stacked vertically one on top of the other.

6. (canceled)

7. The optoelectronic semiconductor device according to claim 1, wherein the detection signal is a periodic signal from which a difference is determined between a frequency of electromagnetic radiation emitted by the surface-emitting laser diode and the frequency of the electromagnetic radiation reflected by the object.

8. An optoelectronic semiconductor apparatus comprising:
a substrate;
a plurality of pixels (11) arranged over the substrate, each comprising a semiconductor layer stack;
a current source and
an evaluation device adapted to determine, from a detection signal of the photodetector, information about a change in distance between the optoelectronic semiconductor device and an object which has reflected the electromagnetic radiation emitted by the surface-emitting laser diode;
wherein the semiconductor layer stack each comprises a surface-emitting laser diode and a photodetector, which are arranged vertically one on top of the other, and the current source is adapted to vary a current intensity impressed into at least one of the surface-emitting laser diodes, thus allowing an emission wavelength to be varied.

9. The optoelectronic semiconductor apparatus according to claim 8, further comprising an array of waveguides adapted to supply electromagnetic radiation reflected by an object to a respective one of the photodetectors.

10. The optoelectronic semiconductor apparatus according to claim 8, wherein the surface-emitting laser diodes each comprise a plurality of laser elements stacked vertically one on top of the other.

11. The optoelectronic semiconductor apparatus according to claim 8, wherein the current source is adapted to impress different current intensities into two different surface-emitting laser diodes, respectively.

12. The optoelectronic semiconductor apparatus according to claim 8, wherein the current source is adapted to drive multiple surface-emitting laser diodes of the plurality of pixels simultaneously.

13. (canceled)

14. The optoelectronic semiconductor apparatus according to claim 8, wherein the detection signal is a periodic signal from which a difference is determined between a frequency of electromagnetic radiation emitted by the surface-emitting laser diode and the frequency of electromagnetic radiation reflected by the object.

15. The optoelectronic semiconductor apparatus according to claim 8, further comprising an optical element adapted to deflect the direction of electromagnetic radiation emitted by some of the pixels.

16. The optoelectronic semiconductor device according to claim 8, further comprising an array of optical micro elements adapted to supply electromagnetic radiation reflected by an object to a respective one of the photodetectors.

17. A method for operating an optoelectronic semiconductor device comprising:
a semiconductor layer stack in which a surface-emitting laser diode and a photodetector are arranged vertically one on top of the other; and
a current source adapted to vary a current impressed in the surface-emitting laser diode, thus allowing an emission wavelength to be varied;
wherein the method comprises:
impressing a current which varies over time into the surface-emitting laser diode, as a result of which electromagnetic radiation is emitted at a frequency which varies over time;
detecting a photocurrent through the photodetector, thereby obtaining a detection signal; and
determining, from the detection signal, a change in a distance between an object reflecting the electromagnetic radiation and the optoelectronic semiconductor device.

18. (canceled)

19. The method according to claim 17, wherein the detection signal is a periodic signal from which a difference is determined between a frequency of electromagnetic radiation which has been emitted by the surface-emitting laser diode and the frequency of the electromagnetic radiation which has been reflected by the object.

20-22. (canceled)
